(19) United States
(12) Patent Application Publication
(10) Pub. No.: US 2025/0365879 A1
(43) Pub. Date: Nov. 27, 2025

(54) ANTI-MISPLUG GUIDING MODULE FOR CPU EMULATOR INSERTION AND ALIGNMENT

(71) Applicant: Aivres Systems Inc., San Jose, CA (US)

(72) Inventor: Hou Ya HSIAO, New Taipei City (TW)

(21) Appl. No.: 19/297,116

(22) Filed: Aug. 12, 2025

(51) Int. Cl. H05K 7/10; G01K 7/24; H05K 7/14; H05K 7/20

(52) U.S. Cl. CPC H05K 7/1084; G01K 7/24; H05K 7/1431; H05K 7/20136

(57) ABSTRACT

An anti-misplug guiding module for mounting a CPU emulator into a motherboard socket is provided. The module includes a frame with upper and lower surfaces, latching structures at the corners for orientation-constrained engagement with a CPU emulator retention fixture, and a chamfered corner alignment structure for enforcing a single correct insertion orientation. The frame includes screw holes for attachment to the emulator and may have a hollow central region and openings to accommodate adapter pins and protruding screws without altering vertical spacing. In some embodiments, a temperature sensing circuit integrated on the lower surface detects localized thermal conditions near the socket. When a threshold is exceeded, a comparator triggers visual indicators and optionally activates a fan via a control circuit.

### TECHNICAL FIELD

The present invention relates to the field of electronic emulation systems, and more particularly to a guiding module for safely and accurately inserting a Central Processing Unit (CPU) emulator into a motherboard socket during board-level validation or various testing.

### BACKGROUND

In motherboard testing environments, CPU emulators such as VRTT5 (Voltage Regulator Test Tool 5) are used to emulate processor behavior for validating power delivery systems, thermal characteristics, and system-level functionality. These emulators are typically mounted into the motherboard socket through a layered assembly that includes a male-to-male adapter, an interposer, and a CPU emulator retention fixture.

Because the male-to-male adapter features a dense array of delicate pins, and the available vertical space is constrained by other fixture components, accurate alignment during insertion is critical. Errors in angle, position, or orientation during manual insertion can result in bent pins, electrical short circuits, or damage to the socket or emulator. The insertion process also offers limited visual feedback, making precise alignment difficult.

Existing setups generally rely on manual alignment without integrated structural guidance, leaving room for user error. In addition, prolonged testing can generate heat that may deform certain materials or affect testing reliability. Therefore, there is a need for a mechanically guided module that facilitates proper orientation and alignment of the CPU emulator, protects against damage, preserves existing spatial tolerances, and optionally incorporates thermal sensing and active cooling features.

### SUMMARY

A system of one or more computers can be configured to perform particular operations or actions by virtue of having software, firmware, hardware, or a combination thereof installed on the system, which, in operation, causes the system to perform the actions. One or more computer programs can be configured to perform particular operations or actions by virtue of including instructions that, when executed by data processing apparatus, cause the apparatus to perform the actions.

In one general aspect, an anti-misplug guiding module may include a frame having a first surface and a second surface. The first surface is configured to be mounted to the bottom of a CPU emulator, and the second surface is configured to guide alignment of the CPU emulator with a CPU emulator retention fixture such that a plurality of pins on a male-to-male adapter positioned within the retention fixture are aligned for insertion into corresponding pin receptacles on the CPU emulator. The anti-misplug guiding module may also include a plurality of screw holes located at the corners of the frame and extending through the frame, the screw holes being configured to receive fasteners for mounting the frame to the bottom of the CPU emulator.

The module may further include a plurality of latching structures disposed at the corners of the second surface of the frame, each latching structure having a right-angle geometry configured to engage with a corresponding corner of the CPU emulator retention fixture to constrain the frame in a predefined orientation. In addition, the module may include a chamfered corner alignment structure formed at one of the latching structures. The chamfered corner alignment structure is configured to mate with a rounded corner of the CPU emulator retention fixture to ensure a single correct orientation during insertion.

Other embodiments of this aspect include corresponding computer systems, apparatuses, and computer programs recorded on one or more computer storage devices, each configured to perform the actions of the described methods.

Implementations may include one or more of the following features. The frame of the anti-misplug guiding module may be made of Bakelite. The frame may have a thickness defined based on a protrusion height of screws on the CPU emulator retention fixture, such that insertion of the frame does not increase the vertical spacing between the CPU emulator and the retention fixture. The anti-misplug guiding module may include a temperature sensing circuit disposed within the frame and on the second surface, configured to detect temperature changes in a region near the motherboard socket. The temperature sensing circuit may include an NTC thermistor and a voltage divider coupled to a comparator. The comparator may be configured to compare a voltage from the voltage divider to a reference voltage and output a signal when a temperature threshold is exceeded. The anti-misplug guiding module may include an LED indicator disposed on the frame, configured to emit a colored light in response to the output signal. The module may also include a fan control circuit configured to activate a fan in response to the output signal. The fan control circuit may include a transistor switch configured to drive the fan when the comparator output indicates that the temperature threshold has been exceeded. The frame may be hollow in a central region between the first and second surfaces to provide clearance for the plurality of pins extending from the male-to-male adapter positioned within the CPU emulator retention fixture. The frame may further include a plurality of openings formed through it, the openings being positioned and dimensioned to receive protruding screws extending from the CPU emulator retention fixture.

Implementations of the described techniques may be realized in hardware, a method or process, or a computer-readable medium.

In another general aspect, a method may include attaching an upper surface of a frame of the anti-misplug guiding module to a bottom surface of the CPU emulator using a plurality of fasteners inserted through screw holes located at the corners of the frame, thereby forming a CPU emulator assembly. The frame may include a plurality of latching structures disposed at the corners of a lower surface of the frame, each having a right-angle geometry configured to engage with a corresponding corner of a CPU emulator retention fixture. One of the latching structures may include a chamfered corner alignment structure.

The method may further include aligning the CPU emulator assembly with a CPU emulator retention fixture installed on a motherboard such that the chamfered corner alignment structure on the frame is aligned with a rounded corner of the retention fixture. The method may also include engaging the CPU emulator assembly with the CPU emulator retention fixture such that a plurality of pins on a male-to-male adapter positioned within the fixture are received into corresponding pin receptacles on the CPU emulator.

Other embodiments of this aspect include corresponding computer systems, apparatuses, and computer programs recorded on one or more computer storage devices, each configured to perform the actions of the method.

### BRIEF DESCRIPTION OF THE DRAWINGS

FIG. 1 illustrates an exploded view of an example CPU emulator assembly including an anti-misplug guiding module, in accordance with some embodiments.

FIG. 2A illustrates an example anti-misplug guiding module, in accordance with some embodiments.

FIG. 2B illustrates another example anti-misplug guiding module, in accordance with some embodiments.

FIG. 3A illustrates an example engagement between the anti-misplug guiding module and a CPU emulator retention fixture, in accordance with some embodiments.

FIG. 3B illustrates an example engagement between an anti-misplug guiding module and a CPU emulator, in accordance with some embodiments.

FIG. 3C illustrates an example engagement among an anti-misplug guiding module, a CPU emulator, and a CPU emulator retention fixture, in accordance with some embodiments.

FIG. 4A illustrates an example anti-misplug guiding module with a temperature control assembly, engaged with a CPU emulator and a CPU emulator retention fixture, in accordance with some embodiments.

FIG. 4B illustrates an example circuit diagram of the temperature sensing assembly of the anti-misplug guiding module, in accordance with some embodiments.

FIG. 5 illustrates an example CPU testing process using the anti-misplug guiding module, in accordance with some embodiments.

FIG. 6 illustrates another example method for mounting a CPU emulator into a motherboard socket using an anti-misplug guiding module, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

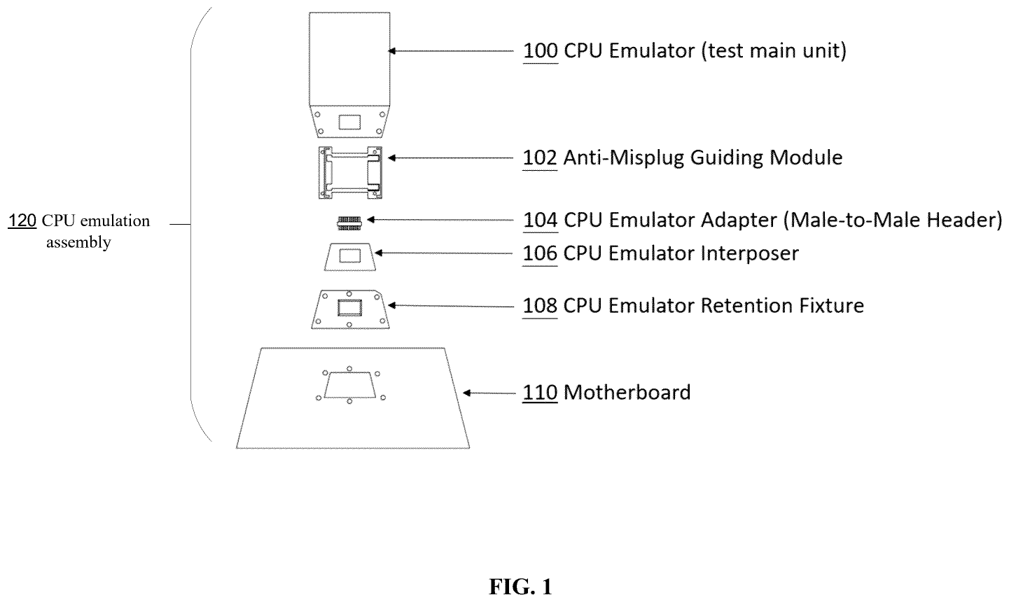

FIG. 1 illustrates an exploded view of an example CPU emulation assembly 120 including an anti-misplug guiding module, in accordance with some embodiments. In FIG. 1, the anti-misplug guiding module 102 is a device designed to address problems that arise in traditional CPU emulation setups during motherboard-level testing. The anti-misplug guiding module 102 will be described in more details in the subsequent disclosure. To understand the function and structural design of the anti-misplug guiding module 102, it is helpful to first understand how the other components of the CPU emulation assembly 120 work together in existing systems.

The depicted CPU emulation assembly 120 may be used for motherboard-level testing and validation, particularly for evaluating power delivery performance, thermal management, and signal integrity in the region of the CPU socket. The CPU emulator 100 emulates the thermal and electrical characteristics of a production CPU, allowing engineers to evaluate board-level designs without installing actual processors. Example CPU emulator 100 may include VRTT5 (Gen5 VR Test Tool Base Kit). The CPU emulator adapter 104, also referred to as a male-to-male header, provides the necessary electrical interface between the emulator and the interposer. The CPU emulator interposer 106 serves as a mechanical and electrical intermediary that adapts the emulator assembly to the socket layout of the motherboard 110. A CPU emulator retention fixture 108 may be secured to the motherboard 110 to hold the entire emulator assembly in place during test operations.

In setups lacking an anti-misplug guiding module, the CPU emulator 100 needs to be manually aligned and inserted onto the male-to-male header 104 and interposer board 106 assembly. This manual insertion process can be challenging due to the dense array and delicate structure of pins, which requires high precision and careful alignment. Without adequate mechanical guidance, insertion errors such as misalignment, angular deviation, or lateral shifts frequently occur. These errors can result in severe technical issues, including bent or damaged pins, electrical short circuits, incomplete electrical connections, damage to the emulator components, and potential degradation of testing accuracy and reliability.

To address these technical issues, the anti-misplug guiding module 102 is introduced as the inventive component. The guiding module 102 is designed to facilitate precise and reliable insertion of the CPU emulator 100 by mechanically constraining its orientation and alignment during assembly. The guiding module 102 ensures that the CPU emulator 100 can only be installed in the correct orientation, accurately aligning pin receptacles on the CPU emulator 100 with corresponding pins of the male-to-male adapter 104. Additionally, the guiding module 102 is designed to maintain existing vertical spacing constraints and includes a plurality of latching structures disposed at corners of the guiding module frame. Each latching structure includes a right-angle geometry configured to engage with corresponding corners of the CPU emulator retention fixture 108, thereby constraining the guiding module in a predefined orientation. At least one of the latching structures incorporates a chamfered corner alignment feature, which mates with a rounded corner of the retention fixture 108 to ensure a single correct orientation during insertion. The guiding module 102 may further be constructed using materials that provide electrical insulation, thermal resistance, and structural rigidity to enhance the reliability and safety of the emulator assembly. As used herein, the term “rounded corner” refers to a corner of a component, such as the CPU emulator retention fixture 108, having a non-right-angled geometry that includes a curved or chamfered surface profile, rather than a sharp or angular edge. The rounded corner may include a fillet, radius, bevel, or similar geometry designed to facilitate mechanical alignment, visual orientation, or keyed engagement with a corresponding structure, such as a chamfered corner alignment structure of the anti-misplug guiding module. The rounded corner serves as a physical reference feature to constrain the orientation of the guiding module 102 during installation.

In some embodiments, the anti-misplug guiding module 102 further integrates a temperature control assembly to support thermal monitoring and protection during testing operations. The temperature control assembly may include a temperature sensor configured to monitor the surface temperature of the CPU emulator 100 or surrounding components in real time. A visual indicator, such as an Light Emitting Diode (LED), may be provided to alert the user to overheating conditions or to confirm safe operation. Additionally, a compact fan may be mounted to the guiding module 102 to provide active cooling when necessary, improving heat dissipation during high-power test cycles.

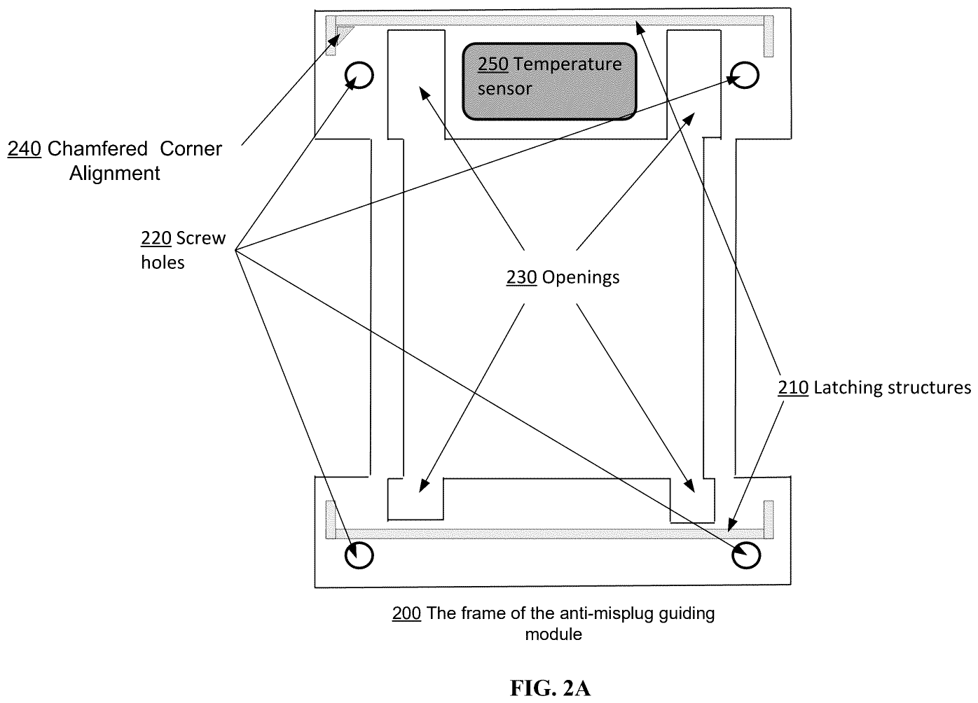

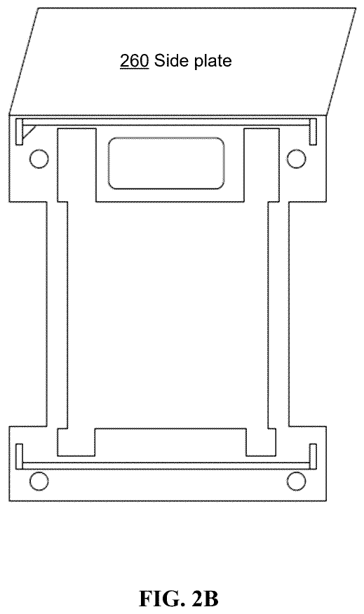

FIG. 2A illustrates an example anti-misplug guiding module, in accordance with some embodiments. FIG. 2A shows structural features and components arranged on a second surface (also referred to as a bottom surface or a lower surface) of a frame 200 of the anti-misplug guiding module. In some embodiments, the guiding module includes two primary surfaces: a first surface, opposite to the illustrated second surface, configured to engage directly with a CPU emulator (such as CPU emulator 100 depicted in FIG. 1), and the second surface, shown in FIG. 2A, configured to interface with a CPU emulator retention fixture (such as retention fixture 108 shown in FIG. 1).

In some embodiments, the second surface of the frame 200 includes a plurality of latching structures 210 disposed at the corners of the frame 200, as shown in FIG. 2A. Each latching structure 210 includes a right-angle geometry that conforms to the adjacent edges of the frame. These latching structures are configured to physically engage with corresponding corners of the CPU emulator retention fixture, thereby constraining the frame 200 into a predefined orientation and guiding the anti-misplug guiding module into precise alignment during installation.

In some embodiments, a chamfered corner alignment structure 240 is integrated into one of the right-angle latching structures 210. This chamfered corner alignment structure 240 is designed to mate with a rounded corner on the CPU emulator retention fixture (such as CPU emulator retention fixture 108 shown in FIG. 1). The chamfered feature ensures that the guiding module—and thus the attached CPU emulator—can only be engaged with the retention fixture in a single, correct orientation.

Although FIG. 2A illustrates one example in which a pair of elongated latching tabs as the latching structure 210 extend along opposing edges of the frame and include two bent ends forming right angles, other configurations may also be used. For example, each latching structure 210 may be implemented as a discrete corner piece positioned individually at each of the four corners of the frame 200. As long as the four right-angle latching structures are present to mechanically constrain the frame within the CPU emulator retention fixture—and at least one of them includes the chamfered corner alignment structure 240—the system can ensure proper orientation and alignment.

The combination of the corner-based latching structures 210 and the chamfered corner alignment structure 240 ensures that the CPU emulator is installed in the correct orientation with respect to the CPU emulator retention fixture. This mechanical alignment guarantees that the plurality of pins on the CPU emulator adapter (e.g., the male-to-male header 104 shown in FIG. 1) are correctly received into the corresponding pin receptacles on the CPU emulator. By enforcing this constrained alignment, the anti-misplug guiding module prevents misaligned mating, thereby reducing risks such as bent pins, electrical shorts, or improper test connections during CPU testing procedures.

In some embodiments, the frame 200 includes a plurality of openings 230. These openings 230 are dimensioned and positioned to accommodate protruding screws that extend upward from the CPU emulator retention fixture, thereby preserving existing vertical spacing constraints and avoiding mechanical interference.

Optionally, a temperature sensor 250 may be integrated into the frame 200 to monitor thermal conditions during CPU testing. During motherboard-level validation, particularly under high-load scenarios or extended test cycles, the CPU emulator can generate substantial heat. Without adequate monitoring, excessive temperature may lead to inaccurate test results, thermal runaway, or even physical damage to the emulator or motherboard socket. By incorporating a temperature sensor 250—and optionally, a visual indicator or a fan—the guiding module can support thermal protection mechanisms. For example, the system may be configured to trigger alerts, throttle emulation behavior, or activate auxiliary cooling when certain thresholds are exceeded.

Designing the anti-misplug guiding module requires addressing several engineering challenges to ensure compatibility with existing CPU emulator testing setups. For example, the thickness of the frame 200 must be carefully determined to avoid introducing any vertical offset between the CPU emulator and the CPU emulator retention fixture. If the guiding module increases the vertical spacing, it could interfere with the proper insertion depth of the pins on the CPU emulator adapter (e.g., male-to-male header 104), potentially leading to unreliable electrical contact or signal degradation.

Additional design considerations include selecting appropriate materials (e.g., Bakelite) to provide thermal insulation and mechanical strength, incorporating temperature monitoring components to protect the system from overheating, and optionally implementing active responses such as LED indicators or fan control to handle excessive thermal buildup.

FIG. 2B illustrates another example anti-misplug guiding module, in accordance with some embodiments. The embodiment illustrated in FIG. 2B is substantially similar to the embodiment shown in FIG. 2A, except for the inclusion of a side plate 260.

In some embodiments, the side plate 260 is a structural component that extends perpendicularly from one edge of the frame 200 of the anti-misplug guiding module. In the example shown in FIG. 2B, the side plate 260 is fixed along a lateral edge of the frame and extends vertically upward from the plane of the frame surface (more specifically, the first surface facing the CPU emulator). The side plate 260 is configured to provide an additional visual and tactile reference for alignment between the anti-misplug guiding module and the CPU emulator. During assembly, an operator may use the side plate 260 as a physical guide to align the guiding module with the side surface of the CPU emulator. This additional alignment feature can help reduce human error during manual installation and ensures proper alignment of the screw holes between the anti-misplug guiding module and the CPU emulator.

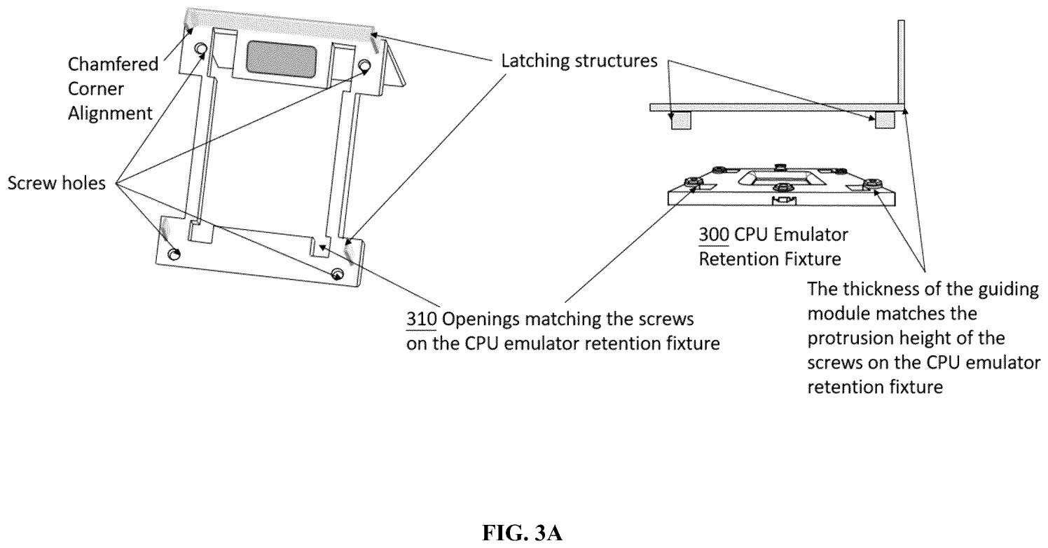

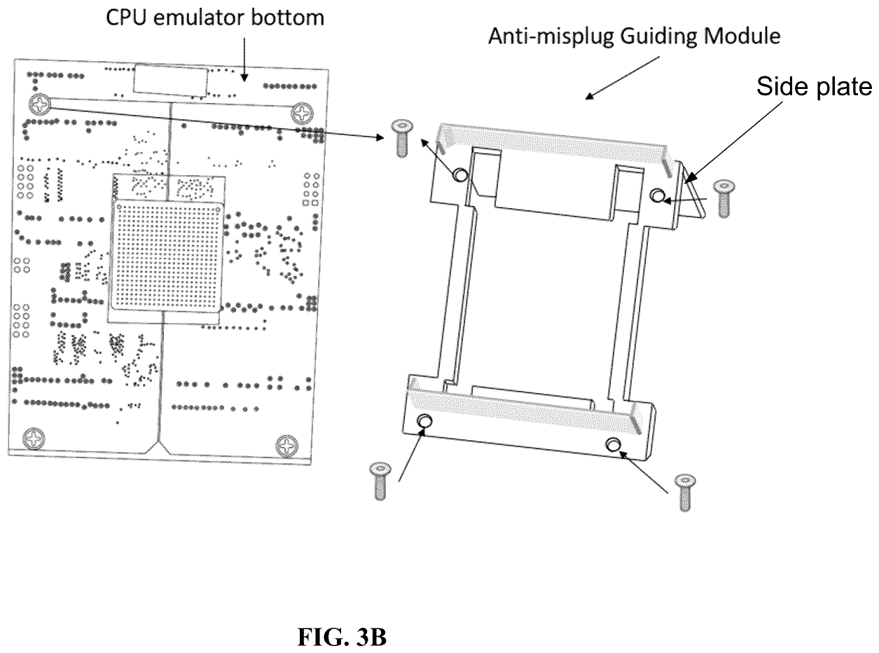

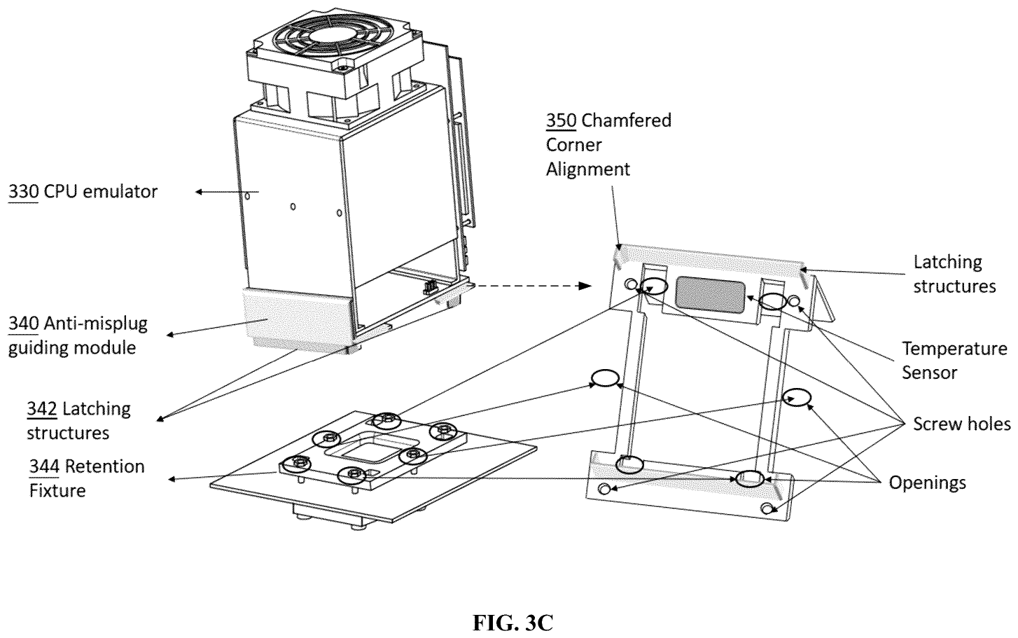

FIG. 3A illustrates an example engagement between the anti-misplug guiding module and a CPU emulator retention fixture, in accordance with some embodiments.

As depicted in FIG. 3A, the anti-misplug guiding module includes openings 310 positioned to align with and accommodate screws protruding upward from the CPU emulator retention fixture 300. The openings 310 ensure that the anti-misplug guiding module lies flat and evenly on top of the CPU emulator retention fixture 300, without adding any extra height or creating space in between. In some embodiments, the anti-misplug guiding module is designed such that its thickness matches the protrusion height of the screws on the retention fixture 300, where “matching” indicates that the anti-misplug guiding module's thickness is equal to or less than this protrusion height. Thus, the overall spacing between the CPU emulator and the CPU emulator retention fixture 300 remains unchanged, preserving the intended insertion depth of connector pins.

Further, FIG. 3A illustrates screw holes positioned at the corners of the guiding module. These screw holes are for receiving fasteners used to secure the guiding module to the CPU emulator. They are not intended to engage or accommodate the screws from the CPU emulator retention fixture 300.

In addition, FIG. 3A shows latching structures located at the corners of the guiding module. These latching structures are configured to align with the corresponding four corners of the CPU emulator retention fixture 300, thereby constraining the guiding module to a predefined orientation and ensuring consistent and correct engagement during insertion.

FIG. 3B illustrates an example engagement between an anti-misplug guiding module and a CPU emulator, in accordance with some embodiments. As shown in FIG. 3B, the anti-misplug guiding module is configured to be positioned beneath the CPU emulator and secured to the emulator bottom surface using a plurality of screws inserted through designated screw holes in the guiding module.

In some embodiments, the guiding module includes one or more vertical side plates (e.g. 260 in FIG. 2B) that extend upward along the edges of the CPU emulator. The one or more side plates serve a mechanical alignment function by interfacing with the corresponding side edges of the CPU emulator. For instance, the interior faces of the side plates are dimensioned to match the lateral dimensions of the CPU emulator, thereby constraining lateral movement and preventing any relative shifting between the guiding module and the emulator during installation or operation.

FIG. 3C illustrates an example engagement among an anti-misplug guiding module 340, a CPU emulator 330, and a CPU emulator retention fixture 344, in accordance with some embodiments. As shown, the anti-misplug guiding module 340 is mounted to the bottom surface of the CPU emulator 330, and interfaces with the CPU emulator retention fixture 344. The anti-misplug guiding module 340 is positioned between the CPU emulator 330 and the retention fixture 344, serving as a mechanical intermediary to enforce correct alignment and prevent misplugging.

The anti-misplug guiding module 340 includes a frame having a first surface configured to engage the CPU emulator 330 and a second surface configured to engage the CPU emulator retention fixture 344. The frame of the anti-misplug guiding module 340 has a thickness defined based on a protrusion height of screws on the CPU emulator retention fixture 344, such that when the anti-misplug guiding module 340 is inserted, it does not increase the vertical spacing between the CPU emulator and the retention fixture. That is, the thickness of the anti-misplug guiding module 340 is equal to or less than the height of the screw heads protruding from the retention fixture, allowing the module to fit and maintain the intended insertion depth of connector pins.

To support this arrangement, the anti-misplug guiding module 340 includes a plurality of openings formed through the frame, each positioned and dimensioned to receive a corresponding screw protruding upward from the CPU emulator retention fixture 344. In the illustrated example, six openings are provided, matching the positions of the six screws on the retention fixture. These openings allow the anti-misplug guiding module 340 to sit flush against the retention fixture, with the screws passing through without interference.

As shown, the anti-misplug guiding module 340 is also hollow in a central region between the first surface and the second surface, thereby providing vertical clearance for a plurality of pins extending from a male-to-male adapter that is secured by the CPU emulator retention fixture 344 and positioned in alignment with the hollowed-out region of the anti-misplug guiding module 340. This hollowed-out region avoids mechanical interference and ensures that no stress is placed on the connector pins.

Additionally, a plurality of latching structures 342 are formed at the corners of the guiding module 340. These latching structures are configured to engage with corresponding corner edges of the retention fixture 344, constraining the guiding module to a predefined orientation. At least one of the latching structures 342 incorporates a chamfered corner alignment feature 350, which aligns with a matching chamfered corner on the retention fixture 344, thereby further enforcing correct orientation during assembly.

The anti-misplug guiding module 340 also includes screw holes for securing the module to the CPU emulator 330. These screw holes are separate and distinct from the openings that receive the screws from the retention fixture. Furthermore, the guiding module may include a temperature sensing circuit or a temperature control assembly to monitor thermal conditions during operation, which will be described in details below.

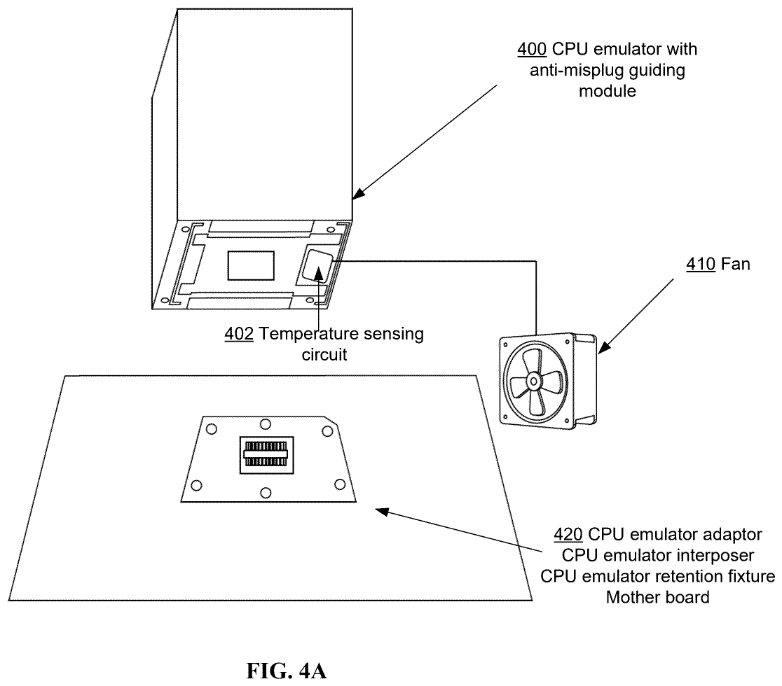

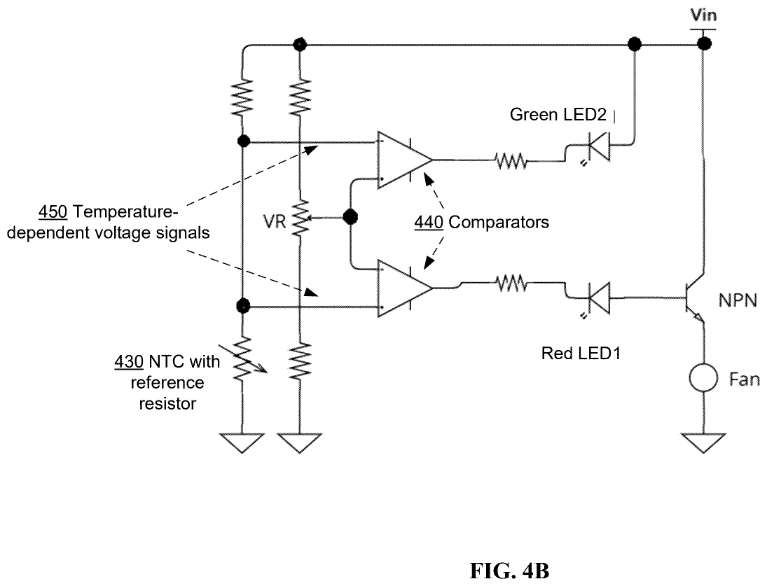

FIG. 4A illustrates an example anti-misplug guiding module with a temperature control assembly, engaged with a CPU emulator and a CPU emulator retention fixture, in accordance with some embodiments. As shown, a CPU emulator 400 with an integrated anti-misplug guiding module is positioned above a CPU emulator adaptor assembly 420, which is mounted on a motherboard. The CPU emulator adaptor assembly 420 may include a CPU emulator adaptor (male-to-male adaptor), a CPU emulator interposer, and a CPU emulator retention fixture, which together provide mechanical support and electrical connectivity between the CPU emulator 400 and the underlying motherboard.

The anti-misplug guiding module integrated into the CPU emulator 400 is configured to guide the insertion of the CPU emulator 400 into the CPU emulator adaptor assembly 420 while enforcing correct orientation and alignment. The guiding module may include latching or orientation structures to constrain insertion to a predetermined direction.

In addition to the above mechanical guiding features, the anti-misplug guiding module may further include a temperature control assembly to enhance thermal management during operation. This temperature control assembly may include a temperature sensing circuit disposed within the frame of the guiding module, on a surface that faces the CPU emulator adaptor assembly 420. The temperature sensing circuit may be configured to monitor the thermal conditions near the socket region of the motherboard. In some embodiments, the temperature sensing circuit may comprise components such as a Negative Temperature Coefficient (NTC) thermistor and a voltage divider coupled to a comparator. When a measured temperature exceeds a threshold, the comparator may output a control signal.

In response to such a control signal, the anti-misplug guiding module may activate a fan 410 positioned adjacent to the CPU emulator. The fan 410 may be thermally coupled to the CPU emulator housing or guiding module and is controlled by a fan control circuit disposed within the module. The fan control circuit may include a transistor-based switching mechanism to drive the fan in response to the comparator output, thereby providing localized cooling.

In some embodiments, a visual indicator such as an LED (not shown in FIG. 4A) may also be included on the guiding module to signal when elevated temperature conditions are detected. The temperature control features described herein support safe and stable operation of the CPU emulator under different thermal loads.

FIG. 4B illustrates an example circuit diagram of the temperature sensing assembly of the anti-misplug guiding module, in accordance with some embodiments. As shown, the example temperature sensing assembly includes a thermistor-based sensing circuit, a comparator-based threshold detection stage, a pair of LED indicators, and a fan control circuit. An NTC thermistor 430 is connected in a voltage divider configuration with a reference resistor to generate a temperature-dependent voltage signal 450. As the surrounding temperature rises, the resistance of the NTC thermistor decreases, resulting in a corresponding drop in the divider output voltage.

This temperature-dependent voltage signal 450 is fed into a comparator (e.g., the bottom one of the two comparators 440 illustrated in FIG. 4B), which also receives a reference voltage from a variable resistor (VR). When the temperature-dependent voltage signal 450 falls below the reference voltage (indicating that the temperature has exceeded a predefined threshold), the output of the comparator changes state.

In the example shown in FIG. 4B, the circuit includes two comparators 430. One comparator output drives LED2, which is a green LED. LED2 may remain lit under normal temperature conditions to indicate safe operation. The second comparator output drives LED1, which is a red LED, and also controls a transistor switch (e.g., a Negative-Positive-Negative (NPN) transistor). When the temperature exceeds the threshold, LED1 illuminates to visually indicate overheating, and the transistor activates a cooling fan connected between the supply voltage (Vin) and ground. When activated, the transistor completes the circuit, allowing current to flow through the fan and enabling its operation.

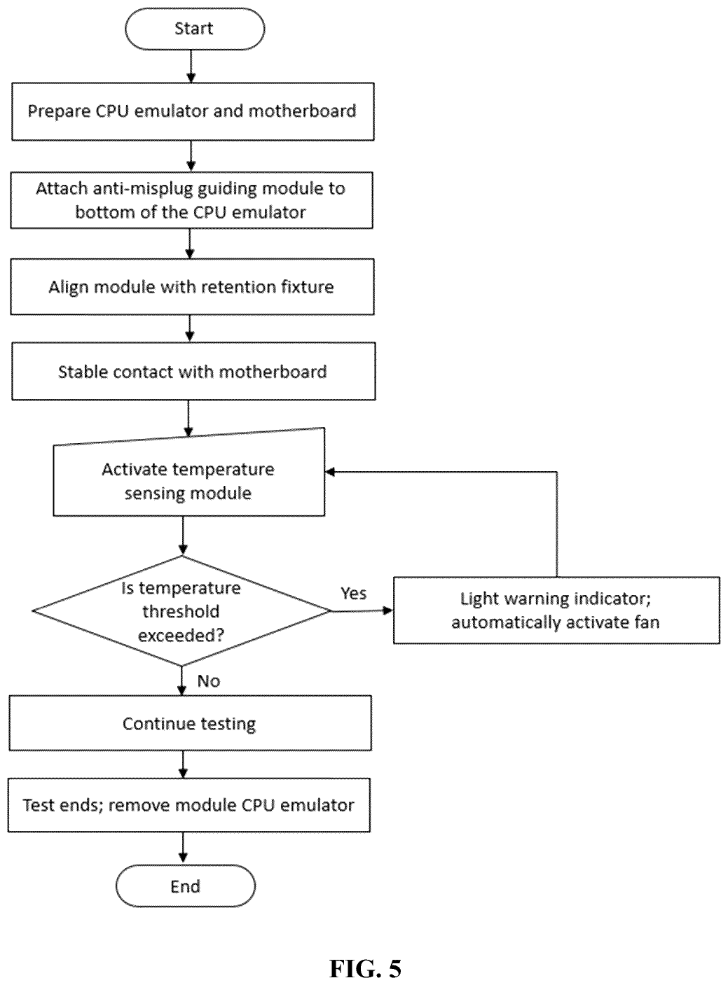

FIG. 5 illustrates an example CPU testing process using the anti-misplug guiding module, in accordance with some embodiments. The process begins with preparation of a CPU emulator and a motherboard, including installing a CPU emulator retention fixture on the motherboard. An anti-misplug guiding module is then attached to the bottom surface of the CPU emulator. In some embodiments, the upper surface (also called the first surface) of the guiding module frame is affixed to the CPU emulator using a plurality of fasteners inserted through screw holes located at the corners of the frame, thereby forming a CPU emulator assembly. The frame of the anti-misplug guiding module includes a plurality of latching structures at the corners of the lower surface (also called the second surface), each having a right-angle geometry configured to engage with corresponding corners of the retention fixture. One of the latching structures includes a chamfered corner alignment structure, which is configured to mate with a rounded corner of the CPU emulator retention fixture, thereby ensuring a single correct orientation for insertion.

Once the CPU emulator assembly is formed, it is aligned with the retention fixture on the motherboard such that the chamfered corner structure on the frame is aligned with the rounded corner of the fixture. The assembly is then inserted into the fixture, during which a plurality of pins on a male-to-male adapter positioned within the retention fixture are received into corresponding pin receptacles on the CPU emulator. Upon successful and stable contact with the motherboard, the temperature sensing module on the frame is activated to monitor for thermal conditions during testing. If the temperature threshold is exceeded during the test, a warning is visually indicated (e.g., by an LED), and a fan is automatically activated for cooling. The test continues under monitored conditions, and once testing concludes, the emulator and anti-misplug guiding module are removed.

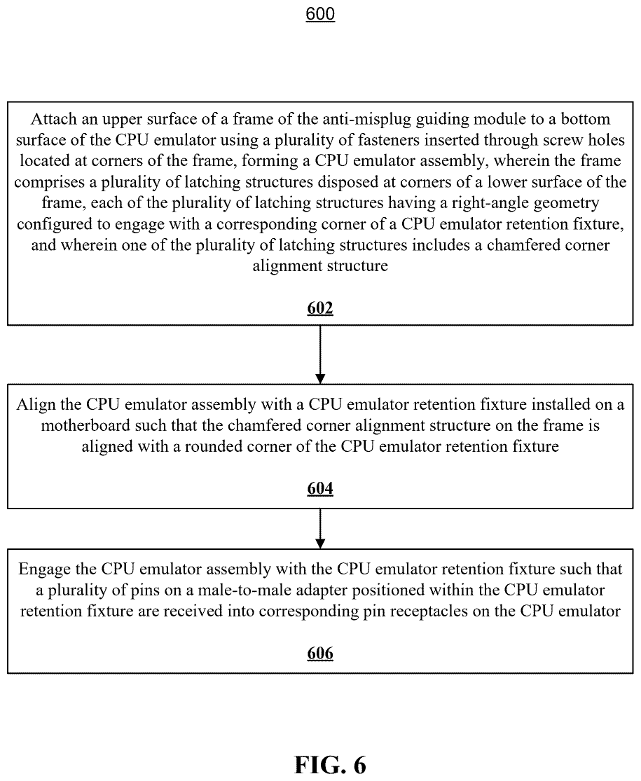

FIG. 6 is a flowchart of an example process 600. In some implementations, one or more blocks of process 600 may be performed by an operator using a device configured to assist with alignment and insertion of a CPU emulator. In some cases, one or more blocks may be performed manually by the operator without the aid of a device.

As shown in FIG. 6, process 600 may include attaching an upper surface of a frame of the anti-misplug guiding module to a bottom surface of the CPU emulator using a plurality of fasteners inserted through screw holes located at the corners of the frame, thereby forming a CPU emulator assembly. The frame may include a plurality of latching structures disposed at corners of a lower surface of the frame, each latching structure having a right-angle geometry configured to engage with a corresponding corner of a CPU emulator retention fixture. One of the latching structures includes a chamfered corner alignment structure (block 602). For example, the operator may attach the frame to the bottom surface of the CPU emulator using fasteners, forming the CPU emulator assembly as described above. Whether performed manually or with the aid of a tool or fixture, this step facilitates proper orientation of the CPU emulator relative to the guiding module.

As also shown in FIG. 6, process 600 may include aligning the CPU emulator assembly with a CPU emulator retention fixture installed on a motherboard such that the chamfered corner alignment structure on the frame is aligned with a rounded corner of the CPU emulator retention fixture (block 604). The alignment may be performed visually and manually by the operator or may be assisted by a positioning device or jig configured to guide the CPU emulator assembly into proper orientation.

As further shown in FIG. 6, process 600 may include engaging the CPU emulator assembly with the CPU emulator retention fixture such that a plurality of pins on a male-to-male adapter positioned within the retention fixture are received into corresponding pin receptacles on the CPU emulator (block 606). This insertion step may be carried out by the operator manually or may be guided by a device or fixture configured to apply controlled pressure or maintain alignment during engagement.

Process 600 may further include additional implementations. In a first implementation, the frame may include a hollow central region configured to provide clearance for the plurality of pins on the male-to-male adapter during insertion.

In a second implementation, which may be combined with the first, the frame may include a plurality of openings formed through the frame, the openings being positioned to receive protruding screws extending from the CPU emulator retention fixture.

In a third implementation, which may be combined with the first and second implementations, process 600 may include monitoring a temperature of a region near the motherboard socket using a temperature sensing circuit disposed on the lower surface of the frame.

In a fourth implementation, which may be combined with any of the first through third implementations, the temperature sensing circuit may include an NTC thermistor and a voltage divider coupled to a comparator.

In a fifth implementation, which may be combined with any of the first through fourth implementations, process 600 may include comparing a voltage output of the voltage divider to a reference voltage using the comparator and generating a warning signal when a temperature threshold is exceeded.

In a sixth implementation, which may be combined with any of the first through fifth implementations, process 600 may include activating a visual indicator on the frame in response to the warning signal.

In a seventh implementation, which may be combined with any of the first through sixth implementations, process 600 may include activating a fan using a fan control circuit in response to the warning signal.

In an eighth implementation, which may be combined with any of the first through seventh implementations, the frame may have a thickness defined based on a protrusion height of screws on the CPU emulator retention fixture such that insertion of the frame does not increase vertical spacing between the CPU emulator and the retention fixture.

Although FIG. 6 shows example blocks of process 600, in some implementations, the process may include additional blocks, fewer blocks, different blocks, or differently arranged blocks than those depicted. Additionally, two or more blocks of process 600 may be performed in parallel. The described method steps may be carried out manually by an operator or performed with partial or full assistance from mechanical or electronic devices configured to facilitate CPU emulator installation and alignment.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuitry.

When the functions disclosed herein are implemented in the form of software functional units and sold or used as independent products, they can be stored in a processor executable non-volatile computer readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, wherein the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of exemplary methods described herein may be performed, at least partially, by an algorithm. The algorithm may be comprised in program codes or instructions stored in a memory (e.g., a non-transitory computer-readable storage medium described above). Such an algorithm may comprise a machine learning algorithm. In some embodiments, a machine learning algorithm may not explicitly program computers to perform a function but can learn from training data to make a prediction model that performs the function.

The various operations of exemplary methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. An anti-misplug guiding module for mounting a CPU emulator into a motherboard socket, comprising:
a frame comprising a first surface and a second surface, wherein the first surface is configured to be mounted to a bottom of the CPU emulator, and the second surface is configured to guide alignment of the CPU emulator with a CPU emulator retention fixture such that a plurality of pins on a male-to-male adapter positioned within the CPU emulator retention fixture are aligned for insertion into corresponding pin receptacles on the CPU emulator;
a plurality of screw holes located at corners of the frame and extending through the frame, the plurality of screw holes being configured to receive fasteners for mounting the frame to the bottom of the CPU emulator;
a plurality of latching structures disposed at corners of the second surface of the frame, each latching structure comprising a right-angle geometry configured to engage with corresponding corner of the CPU emulator retention fixture to constrain the frame in a predefined orientation; and
a chamfered corner alignment structure formed at one of the plurality of latching structures, the chamfered corner alignment structure being configured to mate with a rounded corner of the CPU emulator retention fixture to ensure a single correct orientation during insertion.

2. The anti-misplug guiding module of claim 1, wherein the frame is made of Bakelite.

3. The anti-misplug guiding module of claim 1, wherein the frame has a thickness defined based on a protrusion height of screws on the CPU emulator retention fixture such that the insertion of the frame does not increase a vertical spacing between the CPU emulator and the CPU emulator retention fixture.

4. The anti-misplug guiding module of claim 1, further comprising:
a temperature sensing circuit embedded within the frame and on the second surface, the temperature sensing circuit being configured to detect temperature changes in a region near the motherboard socket.

5. The anti-misplug guiding module of claim 4, wherein the temperature sensing circuit comprises an NTC thermistor and a voltage divider coupled to a comparator.

6. The anti-misplug guiding module of claim 5, wherein the comparator is configured to:
compare a voltage from the voltage divider to a reference voltage, and
output a signal when a temperature threshold is exceeded.

7. The anti-misplug guiding module of claim 6, further comprising:
an LED indicator disposed on the frame, wherein the LED indicator is configured to emit a colored light in response to the output signal.

8. The anti-misplug guiding module of claim 6, further comprising:
a fan control circuit configured to activate a fan in response to the output signal.

9. The anti-misplug guiding module of claim 8, wherein the fan control circuit comprises a transistor switch configured to drive the fan when an output of the comparator exceeds the temperature threshold.

10. The anti-misplug guiding module of claim 1, wherein the frame is hollow in a central region between the first surface and the second surface to provide clearance for a plurality of pins extending from the male-to-male adapter positioned within the CPU emulator retention fixture.

11. The anti-misplug guiding module of claim 1, further comprising:
a plurality of openings formed through the frame, the plurality of openings being positioned and dimensioned to receive protruding screws extending from the CPU emulator retention fixture.

12. A method for mounting a CPU emulator into a motherboard socket using an anti-misplug guiding module, the method comprising:
attaching an upper surface of a frame of the anti-misplug guiding module to a bottom surface of the CPU emulator using a plurality of fasteners inserted through screw holes located at corners of the frame, forming a CPU emulator assembly, wherein the frame comprises a plurality of latching structures disposed at corners of a lower surface of the frame, each of the plurality of latching structures having a right-angle geometry configured to engage with a corresponding corner of a CPU emulator retention fixture, and wherein one of the plurality of latching structures comprises a chamfered corner alignment structure;
aligning the CPU emulator assembly with the CPU emulator retention fixture installed on a motherboard such that the chamfered corner alignment structure on the frame is aligned with a rounded corner of the CPU emulator retention fixture; and
engaging the CPU emulator assembly with the CPU emulator retention fixture such that a plurality of pins on a male-to-male adapter positioned within the CPU emulator retention fixture are received into corresponding pin receptacles on the CPU emulator.

13. The method of claim 12, wherein the frame further comprises a hollow central region configured to provide clearance for the plurality of pins on the male-to-male adapter during insertion.

14. The method of claim 12, wherein the frame further comprises a plurality of openings formed through the frame, the plurality of openings being positioned to receive protruding screws extending from the CPU emulator retention fixture.

15. The method of claim 12, further comprising:
monitoring a temperature of a region near the motherboard socket using a temperature sensing circuit disposed on the lower surface of the frame.

16. The method of claim 15, wherein the temperature sensing circuit comprises an NTC thermistor and a voltage divider coupled to a comparator.

17. The method of claim 16, further comprising:
comparing a voltage output of the voltage divider to a reference voltage using the comparator, and
generating a warning signal when a temperature threshold is exceeded.

18. The method of claim 17, further comprising:
activating a visual indicator on the frame in response to the warning signal.

19. The method of claim 17, further comprising:
activating a fan using a fan control circuit in response to the warning signal.

20. The method of claim 12, wherein the frame has a thickness defined based on a protrusion height of screws on the CPU emulator retention fixture such that the insertion of the frame does not increase a vertical spacing between the CPU emulator and the CPU emulator retention fixture.
